(19) United States
(12) Patent Application Publication
(10) Pub. No.: US 2007/0285909 A1
(43) Pub. Date: Dec. 13, 2007

(54) SYSTEM AND METHOD FOR MOUNTING COMPONENTS ON A PRINTED WIRING BOARD

(75) Inventors: Wiclyff T. Bonga, Tampa, FL (US); William H. Tarver, Largo, FL (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/422,904

(22) Filed: Jun. 8, 2006

(51) Int. Cl. H05K 7/14; H05K 7/18

(52) U.S. Cl. 361/796

(57) ABSTRACT

A printed wiring assembly is provided. The printed wiring assembly comprises a printed wiring board; an electrical component adapted to electrically couple to the printed wiring board via one or more leads; and a mounting device having a base adapted to non-adhesively fasten to the printed wiring board, wherein the base has a cavity formed by at least one side wall and a bottom wall of the base which receives and partially encapsulates the electrical component.

### GOVERNMENT LICENSE RIGHTS

The U.S. Government may have certain rights in the present invention as provided for by the terms of a government contract.

### BACKGROUND

Electrical components, such as transformers, are often not adapted for mechanical connection to a printed wiring board. In such cases, it is common practice to bond the electrical component to the printed wiring board with an approved adhesive, such as epoxy. However, a consistent reliable mechanical support cannot always rely on adhesive strength alone. For example, contamination of the adhesive as well as cure issues can make the adhesive bond unreliable. In addition, operator error in the application of the adhesive is another source of unreliability. Furthermore, using an adhesive has the potential for damaging the printed wiring board, nearby components and/or the electrical component itself if removal of the component is necessary.

For the reasons stated above, and for other reasons stated below which will become apparent to those skilled in the art upon reading and understanding the present specification, there is a need in the art for a reliable system of mounting electrical components on a printed circuit board.

### SUMMARY

The above-menitioned problems and other problems are resolved by the present invention and will be understood by reading and studying the following specification.

In one embodiment, a printed wiring assembly is provided. The printed wiring assembly comprises a printed wiring board; an electrical component adapted to electrically couple to the printed wiring board via one or more leads; and a mounting device having a base adapted to non-adhesively fasten to the printed wiring board, wherein the base has a cavity formed by at least one side wall and a bottom wall of the base which receives and partially encapsulates the electrical component.

In another embodiment, a mounting device for a printed wiring assembly is provided. The mounting device comprises a base adapted to non-adhesively fasten to a printed wiring board, wherein the base has a cavity formed by at least one side wall and a bottom wall of the base which received and partially encapsulates an electrical component such that the electrical component is mechanically coupled to the printed wiring board via the base.

In another embodiment, a method of assembling a printed wiring assembly is provided. The method comprises non-adhesively fastening a mounting a device, having a cavity formed by at least one side wall and a bottom wall, to a printed wiring board; placing an electrical component in the cavity such that the mounting device partially encapsulated the electrical component; and electrically coupling the electrical component to the printed wiring board.

### DRAWINGS

The present invention can be more easily understood and further advantages and uses thereof more readily apparent, when considered in view of the description of the embodiments and the following figures in which:

FIG. 1 is an exploded perspective view in partial cross section of a printed wiring assembly according to one embodiment of the present invention.

FIG. 2 is another block diagram of a printed wiring assembly according to one embodiment of the present invention.

FIG. 3 is block diagram showing the interaction of mounting pegs and peg holes according to one embodiment of the present invention

FIG. 4 is a flow chart showing a method of assembling a printed wiring assembly according to one embodiment of the present invention.

Like reference numbers and designations in the various drawings indicate like elements.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the scope of the present invention. It should also be understood that the exemplary methods illustrated may include additional or fewer steps or may be performed in the context of a larger processing scheme. Furthermore, the methods presented in the drawing figures or the specification are not to be construed as limiting the order in which the individual steps may be performed. The following detailed description is, therefore, not to be taken in a limiting sense.

Embodiments of the present invention enable reliable support of electrical components, such as transformers, by providing a mounting device coupled to a printed wiring board. The strength of support provided by the mounting device to an electrical component is not dependent on adhesive strength alone. In addition, the mounting device is adapted, in various embodiments, to be removable without damaging the printed wiring board, the electrical component, and/or components nearby on the printed wiring board.

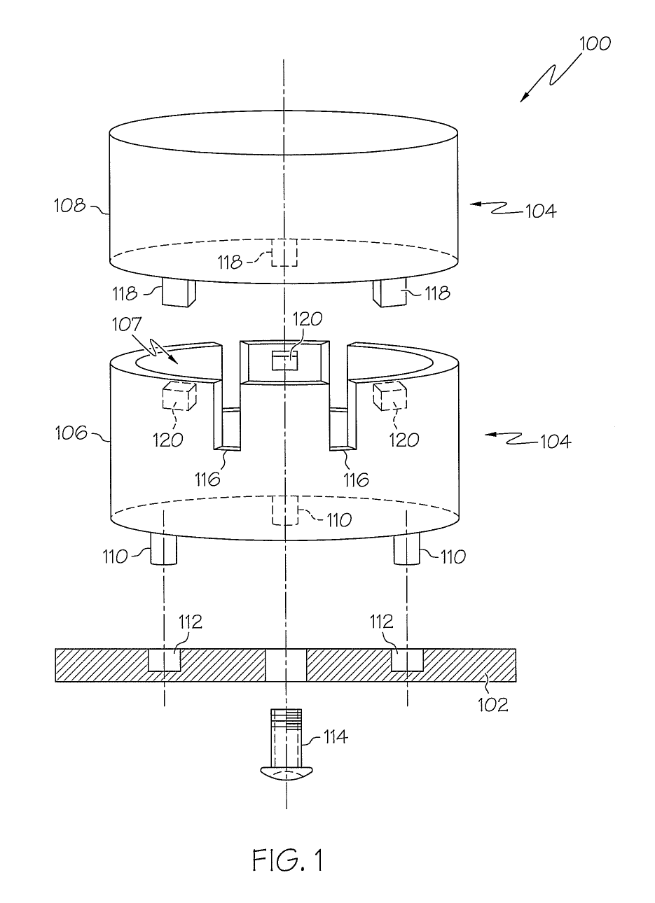

FIG. 1 is an exploded perspective view in partial cross section of a printed wiring assembly 100 according to one embodiment of the present invention. System 100 includes printed wiring board (PWB) 102 and mounting device 104. In this example, mounting device 104 includes base 106 and cover 108. However, it is to be understood that in other embodiments, cover 108 is not included. Mounting device 104, in this example, is made of a thermally conductive plastic. The thermally conductive nature of mounting device 104 enables support of heat transfer as well as mechanical support. However, it is to be understood that mounting device 104 is not required to be made from a thermally conductive material.

In addition, the thermally conductive plastic, in this example, is adapted to be used in injection molding processes to form base 106 and cover 108. Injection molding is a process of inserting heated plastic under high pressure into a mold. The mold defines the shape of the object once the plastic has cooled and hardened. Injection molding is an efficient process for producing multiple bases and covers because it does not require retooling of molds or machines for producing multiple identical bases and covers. However, in other embodiments, other materials and processes are used. For example, in another embodiment, cover 108 and base 106 are produced by combining individual parts as opposed to injection molding. In addition, although base 106 and cover 108 are rounded in this example, any appropriate shape can be used in other embodiments. In particular, both customized sizes and shapes, as well as, standard sizes based on standard electrical component dimensions are used in embodiments of the present invention.

Base 106 is adapted to partially encapsulate an electrical component placed in cavity 107. Cavity 107 is formed by at least one side wall and bottom wall of base 106, as shown in FIG. 1. In particular, base 106 has one circular side wall in FIG. 1. However, it is to be understood that other shapes and numbers of side walls are used in other embodiments. When cover 108 is used, mounting device 104 substantially encapsulates the electrical component. Suitable electrical components include, but are not limited to, transformers and ferrite rotors. Base 106 also includes, in this example, exits 116 which allow lead wires of an electrical component to more easily exit base 106. Base 106 is adapted to non-adhesively fasten to PWB 102. It is to be understood that although base 106 is adapted to non-adhesively fasten to PWB 102, an adhesive may be used as an additional support in some embodiments. Base 106 provides a reliable mechanical support for the at least partially encapsulated electrical component by not relying on adhesive strength alone. Therefore, base 106 does not suffer from the same contamination of adhesive, cure issues and operator error that are sources of unreliability when relying on adhesive strength alone.

In particular, in this example, a mounting screw 114 is used to non-adhesively fasten base 106 to PWB 102. In addition, base 106 is adapted, in this example, with mounting pegs 110. Mounting pegs 110 fit into peg holes 112 in PWB 102 in order to prevent base 106 from spinning about screw 114. This enables easier coupling of base 106 to PWB 102 since base 106 will not spin when mounting screw 114 is turned. In addition, mounting pegs 110 prevent screw 114 from being loosened due to movement of base 106 during operation.

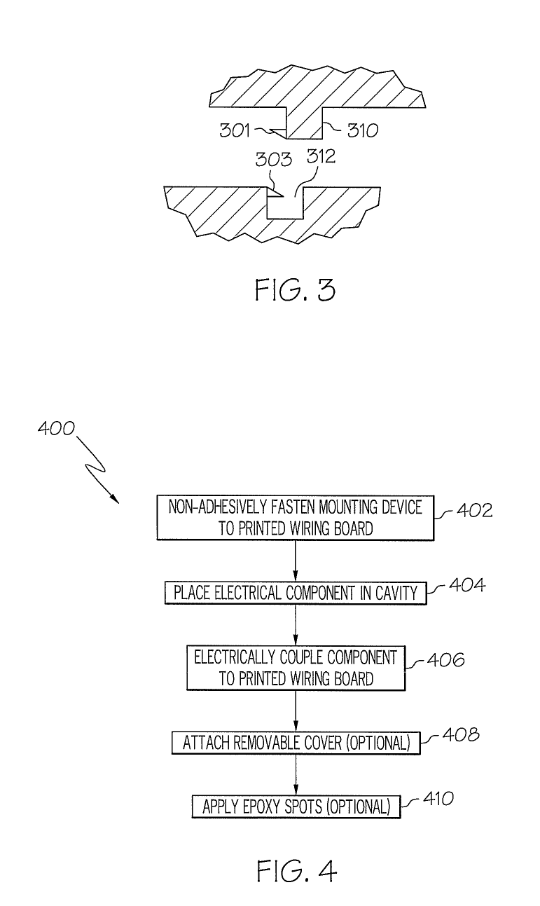

Although only one mounting screw 114 is used in this example, it is to be understood that in other embodiments, more than one mounting screw 114 is used. In addition, in other embodiments, other techniques are used to mechanically couple base 106 to PWB 102. For example, in another embodiment, mounting pegs 110 and peg holes 112 are adapted with mating flanges and grooves (see flanges 301 and grooves 303 in FIG. 3) which interface together forming a “snap” fit when pegs 110 are inserted into peg holes 112. Similarly, cover 108, in this example, is adapted with pegs 118 which “snap” into peg holes 120 securing cover 108 to base 106. However, in other embodiments, other techniques are used to secure cover 108 to base 106, such as clamps, epoxy, etc.

In addition to providing a reliable support for an electrical component, embodiments of the present invention also enable quick and safe removal of the electrical component from printed wiring board 102. For example, in the embodiment in FIG. 1, mounting screw 114 can be loosened enabling base 106 to be removed without damaging printed wiring board 102, other nearby components, or a component encapsulated by mounting device 104. Mounting device 104 can also just as easily be coupled again to printed wiring board 102 by tightening mounting screw 114.

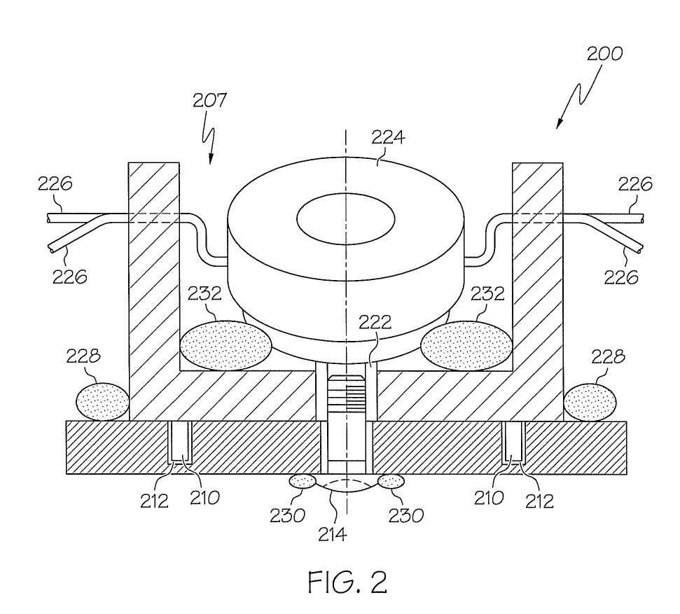

FIG. 2 is another block diagram of a printed wiring assembly 200 according to one embodiment of the present invention. Printed wiring assembly 200 includes base 206 which is non-adhesively fastened to printed wiring board (PWB) 202 via mounting screw 214. As can be seen, screw 214 is received by captive insert 222 in base 206. Captive insert 222 is adapted so that screw 214 does not contact component 224, in this example. In addition to mounting screw 214, base 206 is also coupled to PWB 202 with mounting pegs 210 which fit into peg holes 212. As described above with respect to FIG. 1, mounting pegs 210 prevent base 206 from spinning. Spinning of base 206 could loosen mounting screw 214 during operation, as well as make it more difficult for a user to couple base 206 to printed wiring board 202 when being assembled.

Base 206 is also coupled to PWB 202 with epoxy spots 228 placed at locations around the perimeter of the connection between PWB 202 and base 206. Epoxy spots 228 add additional structural integrity to the connection between base 206 and PWB 202. In this example, additional epoxy spots 230 are also placed such that spots 230 partially overlap mounting screw 214 and PWB 202 to secure mounting screw 214 in place. Hence, mounting screw 214 is limited from spinning and loosening by epoxy spots 230. Notably, although only one mounting screw 214 is used in this embodiment, it is to be understood that, in other embodiments, other numbers of mounting screws are used.

Printed wiring assembly 200 also includes electrical component 224 with leads 226. In this example, component 224 is a transformer. However, in other embodiments, other electrical components are used, such as a ferrite rotor. In this example, component 224 is placed in cavity 207 and secured to base 206 via epoxy spots 232. Epoxy spots 232 add an additional level of support to component 224 without risking damage to PWB 202 or components nearby on PWB 202. However, in other embodiments, epoxy spots 232 are not used. In addition, leads 226 exit base 206 via exit slots (such as exits 116 in FIG. 1) as indicated by the dotted portions of leads 226. Hence, while partial encapsulation of component 224 provides reliable support for component 224, leads 226 are still able to exit base 206 and electrically couple to other components and/or printed wiring board 202.

FIG. 3 is block diagram showing the interaction of mounting pegs 310 and peg holes 312 according to one embodiment of the present invention. As shown in FIG. 3, mounting peg 310 and peg hole 312 are each adapted with flanges 301 and 303, respectively. Flanges 301 and 303 are adapted to deform sufficiently allowing flange 301 to pass flange 303 when nominal pressure is applied to insert mounting peg 310 into peg hole 312. However, the shape of flanges 301 and 303 does not allow the flanges to sufficiently deform under normal operating stresses to permit flange 301 to pass flange 303 allowing mounting peg 310 to exit peg hole 312. Although flanges are used in this embodiment, it is to be understood that, in other embodiments, other means of securing mounting peg 310 in peg hole 312 are used, such as mating rims and grooves.

FIG. 4 is a flow chart showing a method 400 of assembling a printed wiring assembly, such as printed wiring assembly 200 in FIG. 2, according to one embodiment of the present invention. At 402, a mounting device, such as mounting device 104 in FIG. 1, is non-adhesively fastened to a printed wiring board. In this example, a base of the mounting device is fastened to the printed wiring board with a mounting screw. However, in other embodiments, the mounting device is non-adhesively fastened to the printed wiring board using other techniques, such as mating flanges on mounting pegs in the mounting device and peg holes in the printed wiring board, as described above with regards to FIG. 3.

In addition, in some embodiments, the mounting device is adapted with mounting pegs without flanges. Mounting pegs, with or without flanges, help prevent the mounting device from spinning about the mounting screw.

At 404, an electrical component, such as component 224 in FIG. 2, is at least partially encapsulated by the mounting device. That is, an electrical component is placed inside a cavity of the mounting device formed by at least one side wall and a bottom wall of the mounting device base (see base 106 and cavity 107 in FIG. 1). The partially encapsulated component is secured to the base with epoxy spots in some embodiments (see. epoxy spots 232 in FIG. 2). In other embodiments, the epoxy spots are not used. At 406, the electrical component is electrically coupled to the printed wiring board either directly or via electrical contact with other electrical components.

Additionally, in some embodiments, a removable cover, such as cover 108 in FIG. 1, is attached to the base at 408 in order to cover the cavity. In some such embodiments, the cover is secured to the base via pegs attached to the cover, such as pegs 118 in FIG. 1, which fit into mating peg holes in the base, such as peg holes 120 in FIG. 1. It should be noted, however, that in other embodiments, the cover is not used or is secured to the base using different techniques, such as clamps, solder, etc. At 410, in some embodiments, one or more epoxy spots are applied over a portion of the mounting screw and the PWB to secure the mounting screw in place. In addition, in some embodiments, epoxy spots are also placed at locations along a perimeter between the mounting device and the PWB to add structural integrity to the mechanical connection. However, it is to be understood that in other embodiments, epoxy spots are not used.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed is:

1. A printed wiring assembly, comprising:
a printed wiring board;
an electrical component adapted to electrically couple to the printed wiring board via one or more leads; and
a mounting device having a base adapted to non-adhesively fasten to the printed wiring board, wherein the base has a cavity formed by at least one side wall and a bottom wall of the base which receives and partially encapsulates the electrical component.

2. The printed wiring assembly of claim 1, wherein the mounting device further comprises one or more locking pegs adapted to fit into one or more mating peg holes in the printed wiring board.

3. The printed wiring assembly of claim 1, wherein the mounting device is made of a thermally conductive plastic.

4. The printed wiring assembly of claim 1, wherein the mounting device further comprises one or more exit holes for lead wires of the electrical component.

5. The printed wiring assembly of claim 1, wherein the mounting device is adapted to couple to the printed wiring board via at least one mounting screw.

6. The printed wiring assembly of claim 1, wherein the mounting device is made of a material suitable to be used in injection molding processes.

7. The printed wiring assembly of claim 1, wherein the electrical component is a transformer.

8. The printed wiring assembly of claim 1, wherein the mounting device further comprises:
a removable cover adapted to attach to the base covering the cavity.

9. The printed wiring assembly of claim 8, wherein the removable cover further comprises one or more mounting pegs to fit in mating peg holes in the base.

10. A mounting device for a printed wiring assembly comprising:
a base adapted to non-adhesively fasten to a printed wiring board, wherein the base has a cavity formed by at least one side wall and a bottom wall of the base which receives and partially encapsulates an electrical component such that the electrical component is mechanically coupled to the printed wiring board via the base.

11. The mounting device of claim 10, wherein the base is adapted to couple to the printed wiring board via at least one mounting screw.

12. The mounting device of claim 10, wherein the base is made of a thermally conductive material.

13. The mounting device of claim 10, wherein the base further comprises one or more mounting pegs adapted to fit in mating peg holes in the printed wiring board.

14. The mounting device of claim 10, further comprising:
a removable cover adapted to couple to the base.

15. The mounting device of claim 14, wherein the removable cover couples to the base via one or more pegs adapted to fit in mating grooves in the base.

16. A method of assembling a printed wiring assembly, the method comprising:
non-adhesively fastening a mounting device, having a cavity formed by at least one side wall and a bottom wall, to a printed wiring board;
placing an electrical component in the cavity such that the mounting device partially encapsulates the electrical component; and
electrically coupling the electrical component to the printed wiring board.

17. The method of claim 16, further comprising attaching a removable cover to the mounting device to cover the cavity.

18. The method of claim 16, wherein placing the electrical component in the cavity further comprises coupling the electrical component to the mounting device with an adhesive.

19. The method of claim 16, wherein non-adhesively fastening the mounting device to the printed wiring board further comprises non-adhesively fastening the mounting device to the printed wiring board with one or more mounting screws.

20. The method of claim 19, further comprising placing an adhesive on the one or more mounting screws such that the adhesive overlaps at least part of the one or more mounting screws and a part of the printed wiring board.
